(19) United States
(12) Patent Application Publication
(10) Pub. No.: US 2026/0140291 A1
(43) Pub. Date: May 21, 2026

(54) OPTICAL MEMBER AND FAR-INFRARED SENSOR MODULE

(71) Applicant: AGC INC., Tokyo (JP)

(72) Inventors: Yuta NAKAYAMA, Tokyo (JP); Yoji YASUI, Tokyo (JP); Yu ONOZAKI, Tokyo (JP); Yuji UGAWA, Tokyo (JP); Tomoaki SAKURADA, Tokyo (JP)

(73) Assignee: AGC INC., Tokyo (JP)

(21) Appl. No.: 19/441,602

(22) Filed: Jan. 6, 2026

Related U.S. Application Data
(63) Continuation of application No. PCT/JP2024/021751, filed on Jun. 14, 2024.

(30) Foreign Application Priority Data
Jul. 12, 2023 (JP) 2023-114442

(51) Int. Cl. G02B 5/20; G02B 1/04; G02B 1/113; H10F 77/30

(52) U.S. Cl. CPC G02B 5/208; G02B 1/04; G02B 1/113; G02B 5/206; H10F 77/331

(57) ABSTRACT

To provide an optical member that appropriately transmits far-infrared rays having a wavelength of 8 μm to 12 μm and exhibits white color. In the present invention, in a CIE 1976 (L⁺, a⁺, b⁺) color space measured by an SCE method based on geometric condition c of JIS-Z8772:2009, L⁺ is 50 or more, a⁺ is −15 or more and 15 or less, and b⁺ is −15 or more and 15 or less, and an average transmittance T_{PIR} (%) of light having a wavelength of 8 μm to 12 μm satisfies T_{FIR}≥20.

### CROSS-REFERENCE TO RELATED APPLICATION(S)

This application is a continuation of International Application No. PCT/JP2024/021751, filed on Jun. 14, 2024 which claims the benefit of priority of the prior Japanese Patent Application No. 2023-114442, filed on Jul. 12, 2023, the entire contents of which are incorporated herein by reference.

### BACKGROUND OF THE INVENTION

### 1. Field of the Invention

The present invention relates to an optical member and a far-infrared sensor module including the optical member.

### 2. Description of the Related Art

Various optical devices utilizing infrared rays, such as an infrared camera or an infrared temperature sensor, are known. In these optical devices, infrared rays reflected by an object or infrared rays emitted from an object are condensed by an optical element for infrared rays to form an image of a subject or to detect the temperature distribution of the object, based on the amount of received infrared rays.

In such an optical element, an antireflection structure is provided on the surface thereof to suppress surface reflection of infrared rays, thereby increasing the infrared transmittance of the optical element. JP 2016-18081 A discloses an infrared-transmitting base material having an antireflection structure composed of a plurality of fine recessed portions.

JP 2022-78336 A discloses an infrared-transmitting optical filter that includes a matrix and fine particles dispersed in the matrix. It is described that the optical filter has a linear transmittance of 60% or more with respect to light having at least a part of wavelengths within a wavelength range of 760 nm or more and 2000 nm or less, and can exhibit a white appearance.

It has been demanded for an optical member that exhibits a white appearance and transmits far-infrared rays having a wavelength of 8 μm to 12 μm. However, an optical member capable of appropriately transmitting far-infrared rays and having a white appearance is not known.

The infrared-transmitting base material disclosed in JP 2016-18081 A is excellent in far-infrared transmittance properties, but is weak in scattering to visible light, and is presumed to have a gray appearance.

The infrared-transmitting optical filter disclosed in JP 2022-78336 A is capable of exhibiting white color. However, it is presumed that each of a substrate and a film constituting the optical filter does not transmit far-infrared rays, and the optical filter also does not transmit far-infrared rays. It is presumed that the film does not transmit far-infrared rays because the film uses a resin that absorbs far-infrared rays and has a large thickness.

### SUMMARY OF THE INVENTION

It is an object of the present invention to at least partially solve the problems in the conventional technology.

Present disclosure may provide optical member as follows.

An optical member, wherein in a CIE 1976 (L⁺, a⁺, b⁺) color space measured by an SCE method based on geometric condition c of JIS-Z8772:2009, L⁺ is 50 or more, a⁺ is −15 or more and 15 or less, and b⁺ is −15 or more and 15 or less, and an average transmittance T_{FIR} (%) of light having a wavelength of 8 μm to 12 μm satisfies T_{FIR}≥20.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic cross-sectional view of an optical member according to one embodiment of the present invention;

FIG. 2 is a schematic cross-sectional view of an optical member according to one embodiment of the present invention;

FIG. 3 is a diagram illustrating a relationship between transmittance and L⁺ of an optical member; and

FIG. 4 is a diagram illustrating a relationship between a particle diameter of fine particles and transmittance, and L⁺ of the optical member.

### DETAILED DESCRIPTION OF THE PREFERRED EMBODIMENTS

For clarity of explanation, the following descriptions and drawings are simplified as appropriate, and the scales of the individual members in the drawings may differ significantly.

In the present specification, “to” indicating a numerical range is used to mean that, unless otherwise specified, the numerical values described before and after “to” are inclusive of a lower limit value and an upper limit value.

In the present specification, the “average transmittance” in a specific wavelength range refers to the arithmetic mean of transmittances at 1 nm intervals within the wavelength range.

In the present specification, the “average attenuation coefficient” in a specific wavelength range refers to the arithmetic mean of attenuation coefficients at 1 nm intervals within the wavelength range.

In the present specification, the “visible light” refers to light having a wavelength of 380 nm to 780 nm unless otherwise specified. In addition, unless otherwise specified, the “far-infrared ray” refers to light having a wavelength of 8 μm to 12 μm, but may be light having a wavelength of 8 μm to 14 μm.

### A. Optical Member

In an optical member according to the present invention (hereinafter, also referred to as “the present member”), in a CIE 1976 (L⁺, a⁺, b⁺) color space measured by an SCE method based on geometric condition c of JIS-Z8772:2009, L⁺ is 50 or more, a⁺ is −15 or more and 15 or less, and b⁺ is −15 or more and 15 or less. Hereinafter, L⁺a⁺b⁺ obtained by the above-described method is referred to as L⁺a⁺b⁺.

When L⁺a⁺b⁺ is in the above-described range, the present member exhibits a white appearance. From the viewpoint of further enhancing the whiteness of the appearance, L⁺ of the present member is preferably 60 or more, more preferably 70 or more, and still more preferably 80 or more. From the same viewpoint, a⁺ of the present member is preferably −10 or more and 10 or less, more preferably −8 or more and 8 or less, and still more preferably −5 or more and 5 or less. From the same viewpoint, b⁺ of the present member is preferably −10 or more and 10 or less, more preferably −8 or more and 8 or less, and still more preferably −5 or more and 5 or less.

In the present member, the average transmittance T_{FIR} (%) of light having a wavelength of 8 μm to 12 μm is T_{FIR}≥20. When the average transmittance T_{FIR} of light having a wavelength of 8 μm to 12 μm is in the above-described range, the present member can appropriately transmit far-infrared rays. The average transmittance T_{FIR} of light having a wavelength of 8 μm to 12 μm of the present member is preferably T_{FIR}≥30, more preferably T_{FIR}≥40, still more preferably T_{FIR}≥50, particularly preferably T_{FIR}≥60, and most preferably T_{FIR}≥70.

In the present member, the sum (L⁺+T_{FIR}) of L⁺ and the average transmittance T_{FIR} of light having a wavelength of 8 μm to 12 μm is preferably 90 or more, more preferably 100 or more, still more preferably 115 or more, particularly preferably 130 or more, and most preferably 145 or more. When (L⁺+T_{FIR}) is in the above-described range, both excellent whiteness and excellent far-infrared transmittance properties can be further attained.

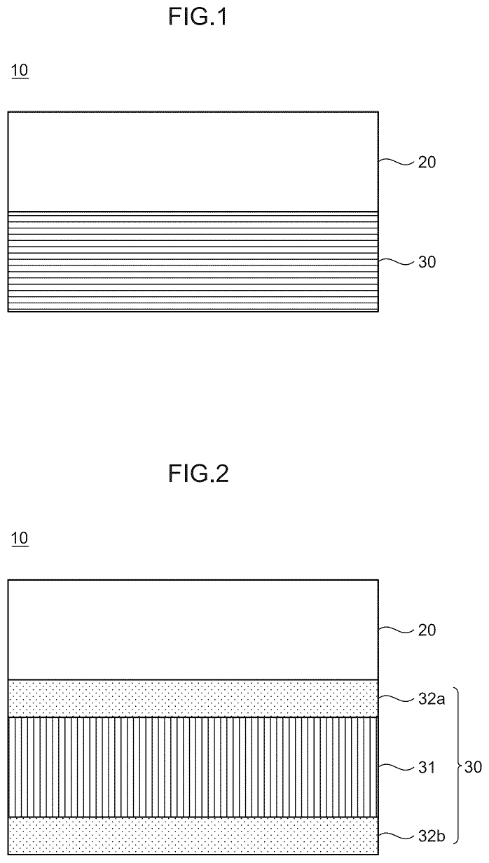

FIG. 1 is a schematic cross-sectional view of a preferred configuration of the present member. As i-lustrated in FIG. 1, the present member 10 may include a white layer 20 that scatters visible light and a base material 30.

Hereinafter, unless otherwise specified, in the present member 10, a main surface closer to the white layer 20 than the base material 30 is defined as a light incident side, and a main surface opposite to the main surface is defined as a light emitting side.

From the viewpoint of enhancing the far-infrared transmittance properties, as illustrated in FIG. 2, the base material 30 preferably has a far-infrared antireflection film 32.

In FIG. 2, the base material 30 includes a support base material 31, a far-infrared antireflection film 32a present between the base material 30 and the white layer 20, and a far-infrared antireflection film 32b present on the side farther from the white layer of the base material 30. The base material 30 may have only one of the far-infrared antireflection films 32a and 32b. From the viewpoint of further enhancing the far-infrared transmittance properties, the present member 10 preferably includes the far-infrared anrtireflection film 32a and the far-infrared antireflection film 32b. Unless otherwise specified, the far-infrared antireflection film 32a and the far-infrared antireflection film 32b are appropriately described as the far-infrared antireflection film 32 when not distinguished from each other.

The present member 10 may further include other functional lavers as long as the effects of the present invention are not impaired. Examples of the other functional layer include an adhesion layer, a protective layer, and an ultraviolet absorbing layer.

Hereinafter, the white layer 20 and the base material 30 will be described in detail.

### A-1. White Layer

The white layer 20 may contain a resin matrix and fine particles dispersed in the resin matrix.

When the material of the fine particles, the particle diameter of the fine particles, the concentration of the fine particles, the thickness of the white layer, and the like are appropriately selected, the white layer 20 can appropriately scatter visible light by Mie scattering, and scattering of far-infrared rays in the white layer 20 can be suppressed.

The particle diameter of the fine particles can be evaluated by the average diameter of the fine particles in the cross section of the white layer 20. The average diameter of the fine particles in the cross section of the white layer 20 is preferably 0.1 m or more, more preferably 0.12 μm or more, and still more preferably 0.15 μm or more. When the average diameter of the fine particles in the cross section of the white layer 20 is in the above-described range, visible light can be appropriately scattered by Mie scattering, and a white appearance can be easily obtained.

The average diameter of the fine particles in the cross section of the white layer 20 is preferably 1 μm or less, more preferably 0.7 μm or less, and still more preferably 0.5 μm or less. When the average diameter of the fine particles in the cross section of the white layer 20 is in the above-described range, scattering of far-infrared rays in the white layer 20 is suppressed, high far-infrared transmittance is easily obtained, and visible light can be appropriately scattered by Mie scattering, and a white appearance is easily obtained.

The fine particles may be present as primary particles or as secondary particles. In a case where the fine particles are present as secondary particles, the average diameter means the average diameter of the secondary particles.

A method for measuring the average diameter of the fine particles in the cross section of the white layer 20 will be described later in Examples.

As the fine particles, inorganic fine particles can be used. From the viewpoint of having a high refractive index to visible light and easily scattering visible light, the fine particles preferably include at least one selected from the group consisting of SiO₂, a metal oxide, Si, Ge, Group II-VT semiconductor, and Group III-V semiconductor. It is more preferable that the fine particles include at least one of SiO; or a metal oxide because the fine particles are transparent to visible light and a white appearance is easily obtained. In particular, it is more preferable that the fine particles include at least one selected from the group consisting of TiO₂, ZrO₂, Nb₂O₅, and Ta₂O₅ because of high refractive index. Among these, the fine particles most preferably include TiO₂ because ultrafine particles are easily obtained and the refractive index is high.

The volume concentration of fine particles in the white layer 20 is preferably 4% or more, preferably 10% or more, more preferably 15% or more, and still more preferably 18% or more. When the volume concentration of the fine particles is in the above-described range, sufficient scattering intensity is exhibited with respect to visible light without excessively increasing the thickness of the white layer 20, and a white appearance is easily obtained.

The volume concentration of the fine particles in the white layer 20 is preferably 80% or less, more preferably 50% or less, and still more preferably 30% or less. When the volume concentration of the fine particles is in the above-described range, the fine particles are well dispersed in the resin matrix, and scattering and absorption of far-infrared rays by the fine particles are suppressed, resulting in high far-infrared transmittance being more easily achieved.

The resin matrix retains the fine particles dispersed in the resin matrix.

Since the present member 10 may be attached to a surface of an optical device as a sensor cover, it is preferable to use a resin having excellent weather resistance as the resin matrix. When a resin having high weather resistance is used for the resin matrix, not only deformation and deterioration of the white layer 20 can be minimized, but also deterioration of design property due to discoloration can be minimized. From the viewpoint of increasing the transmittance of far-infrared rays, it is preferable to use a resin that absorbs less far-infrared rays as the resin matrix.

The refractive index of the resin matrix with respect to light having a wavelength of 550 nm is preferably 1.5 or less, more preferably 1.4 or less, and still more preferably 1.3 or less. When the refractive index of the resin matrix is in the above-described range, a difference in refractive index between the resin matrix and the fine particles is likely to increase, and visible light is likely to be scattered.

The refractive index of the resin matrix for light having a wavelength of 550 nm is generally 1 or more.

The resin used for the resin matrix is only required to be able to retain fine particles in a dispersed state. Although a specific material is optional, it is preferable that the resin matrix contains at least one of a fluororesin or a polyolefin resin in consideration of the refractive index, weather resistance, and far-infrared transmittance properties of the resin matrix.

In particular, the resin matrix preferably contains a fluororesin as a resin having high weather resistance. Specific examples of the fluororesin include a vinyl fluoride resin, a vinylidene fluoride resin, an ethylene-tetrafluoroethylene resin, a chlorotrifluoroethylene resin, a chlorotrifluoroethylene-ethylene resin, a tetrafluoroethylene-hexafluoropropylene resin, and a tetrafluoroethylene-perfluoro (alkyl vinyl ether) resin. From the viewpoint of immobilization of fine particles and durability against oxidizing power, the fluororesin is preferably an ethylene-tetrafluoroethylene resin, a tetrafluoroethylene-hexafluoropropylene resin, or a tetrafluoroethylene-perfluoro (alkyl vinyl ether) resin.

As the resin having the particularly enhanced far-infrared transmittance properties, it is preferable to use a resin having a molecular structure with low absorption in the wavelength range of 8 μm to 12 μm, and it is preferable to contain a polyolefin resin. Examples of the polyolefin resin include polyethylene and high-density polyethylene.

From the viewpoint of sufficiently scattering visible light to obtain a white appearance, the thickness of the white layer 20 is preferably 1 μm or more, more preferably 2 μm or more, and still more preferably 4 μm or more. From the viewpoint of suppressing absorption of far-infrared rays by the resin matrix and obtaining high transmittance of far-infrared rays, the thickness of the white layer 20 is preferably less than 10 μm, more preferably less than 8 μm, and still more preferably less than 7 μm.

In a case where the resin matrix contains the resin having the particularly enhanced far-infrared transmittance properties described above, the transmittance of far-infrared rays is less likely to decrease even though the white layer 20 is thick. Therefore, when the resin matrix contains the resin having the particularly enhanced far-infrared transmittance properties described above, the thickness of the white layer 20 is preferably less than 100 μm, more preferably less than 60 μm, still more preferably less than 40 μm, particularly preferably less than 15 μm, yet still more preferably less than 10 μm, and most preferably less than 7 pin. When the thickness of the white layer 20 is within the above-described range, absorption of far-infrared rays by the resin matrix can be suppressed.

Examples of the method for forming the white layer 20 include a method in which a white layer precursor containing a curable resin matrix and fine particles is applied onto the base material 30 to form a film using a method such as spin coating, curtain coating, flow coating, dip coating, spray coating, screen coating, or inkjet printing. The white layer precursor may contain a solvent and various additives.

In the white layer precursor, the fine particles are dispersed in the resin matrix by, for example, rotary stirring, a homomixer, an ultrasonic homogenizer, a high-pressure homogenizer, or high-temperature spraying.

### A-2. Base Material

The base material 30 transmits far-infrared rays. From the viewpoint of increasing the far-infrared transmittance of the present member, the average transmittance of light having a wavelength of 8 μm to 12 μm of the base material 30 is preferably 30% or more, more preferably 40% or more, still more preferably 45% or more, particularly preferably 60% or more, yet still more preferably 70% or more, and most preferably 75% or more.

From the viewpoint of enhancing the strength or the present member 10, the thickness of the base material 30 is preferably 0.1 r or more, more preferably 0.2 r or more, and still more preferably 0.3 mm or more.

From the viewpoint of ensuring the far-infrared transmittance properties of the present member 10 and thinning the present member 10, the thickness of the base material 30 is preferably 5 mm or less, more preferably 2 r or less, and still more preferably 1 r or less.

The base material 30 includes a support base material 31. In a case where the base material 30 does not include a film other than the support base material 31, such as a far-infrared antireflection film, the support base material 31 itself can be used as the base material 30.

It is preferable that the support base material 31 contains at least one selected from the group consisting of a Si base material, a Ge base material, a ZnS base material, and a chalcogenide glass base material because of excellent far-infrared transmittance properties. Among these, the support base material 31 more preferably includes at least one of a Si base material and a Ge base material because of a high refractive index with respect to visible light. When the refractive index of the support base material 31 with respect to visible light is high, visible light transmitted through the white layer and reaching the support base material 31 is easily reflected at the interface of the support base material 31. When the visible light is reflected at the interface of the support base material 31, the reflected visible light is incident on the white layer again and scattered, so that a white appearance is easily obtained.

The refractive index of the support base material 31 with respect to light having a wavelength of 550 nm is preferably 2 or more, more preferably 3 or more, and still more preferably 4 or more. The refractive index of the support base material 31 is not particularly limited, but may be generally 4.5 or less.

In a case where the support base material 31 contains a chalcogenide glass, the chalcogenide glass preferably contains, in terms of atom %:
7% to 25% of Ge Ga;
0% to 35% of Sb;
0% to 20% of Bi;
0% to 20% of Zn;
0% to 20% of Sn;
0% to 20% of Si;
0% to 20% of La;
55% to 80% of S Se+Te,
0.005% to 0.3% of Ti;
0% to 20% of Li±Na+K+Cs;
0% 20% of F+Cl+Br+I. The chalcogenide glass preferably has a glass transition point (Tg) of 140° C. to 55° C.

### A-2-1. Far-Infrared Antireflection Film

The far-infrared antireflection film 32 suppresses reflection of far-infrared rays on the main surface of the base material on the side farther from the white layer or at the interface between the white layer and the base material.

The attenuation coefficient of the far-infrared antireflection film 32 for light having a wavelength of 10 μm is preferably 0.05 or less, more preferably 0.03 or less, still more preferably 0.025 or less, particularly preferably 0.02 or less, and most preferably 0.01 or less. When the attenuation coefficient for light having a wavelength of 10 μm is in the above-described range, the reflectance of far-infrared rays can be reduced, and the far-infrared rays can be appropriately transmitted. The attenuation coefficient of the far-infrared antireflection film 32 with respect to light having a wavelength of 10 m can be determined by performing fitting of an optical model using, for example, polarization information obtained by an infrared spectroscopic ellipsometer (IR-VASE-UT manufactured by J. A. Woollam Company) and a spectral transmission spectrum obtained by a Fourier transform infrared spectrometer (Nicolet iS10 manufactured by Thermo Fisher Scientific Inc.).

The far-infrared antireflection film 32 contains, for example, at least one of Si, Ge, ZnS, ZnSe, YF₃, MgF₂, diamond-like carbon, or a metal oxide. As the metal oxide used for the far-infrared antireflection film 32, at least one of NiO, Al₂O₃, CuO, ZnO, ZrO₂, Bi₂O₃, Y₂O₃, and MgO is preferable because the attenuation coefficient for far-infrared rays is low. The far-infrared antireflection film 32 preferably contains at least one material selected from the group consisting of NiO, diamond-like carbon, ZrO₂, ZnS, ZnSe, Ge, Si, MgO, ZnO, YF₃, and MgF₂ because the attenuation coefficient for far-infrared rays is low. From the viewpoint of environmental resistance and ease of manufacture, the far-infrared antireflection film 32 preferably contains a metal oxide as a main component. Here, the “main component” means that the content of the far-infrared antireflection film 32 with respect to the entirety is 50 mass % or more. Among the metal oxides, the far-infrared antireflection film 32 preferably contains at least one material selected from the group consisting of NiO, CuO, ZnO, ZrO₂, Bi₂O₃, Y₂O₃, and MgO as a main component because the attenuation coefficient for far-infrared rays is low.

The far-infrared antireflection film 32 can be formed by sputtering or vapor deposition, for example. From the viewpoint of improving adhesion between the far-infrared antireflection film 32 and the support base material 31, it is preferable to form the film by sputtering. In a case where the far-infrared antireflection film 32 contains NiO, it is preferable to form the far-infrared antireflection film 32 by setting the surface of the support base material 31 to 100° C. to 300° C.

### B. Applications

The optical member 10 according to the present invention is suitable as a member used for a far-infrared sensor module because of the appropriate transmission of far-infrared rays and the exhibition of a white appearance. In addition, the far-infrared sensor module using the optical member 10 according to the present embodiment is particularly suitable under an environment in which the far-infrared sensor module is installed while being exposed to the outside because of the exhibition of favorable designability Specific applications include an in-vehicle sensor, a sensor mounted on a drone, a sensor for a monitoring camera, a sensor mounted on a smartphone, a sensor for a wearable terminal, a sensor mounted on a home appliance, a sensor for street lighting, a sensor for an IP camera, a motion sensor, and the like.

### EXAMPLES

Hereinafter, the present invention will be specifically described with reference to examples and comparative examples, but the present invention is not limited thereto. Examples 5 to 13, 18, and 19 are examples, and Examples 1 to 4 and 14 to 17 are comparative examples. Each characteristic of Examples 11 to 19 was calculated by simulation.

The following describes a method for measuring each characteristic of Examples 1 to 10.

### Average Diameter of Fine Particles and Fine Particle Concentration in Cross Section of White Layer

A white layer prepared was subjected to CP processing to obtain a sample for SEM observation. Using SEM (SU8230, manufactured by Hitachi High-Tech Corporation), the sample for PEM observation was observed under the following conditions.
Conductive coating: none
Detector: LA
Acceleration voltage: 2 kV
Magnification: ×20000

The SEM image obtained through observation was imported into the image processing software Image j, and binarization was performed using “Threshold (Otsu, B&W)”. The volume concentration of the fine particles was calculated from the ratio of the area occupied by the fine particles in the image after binarization. The average diameter of fine particles in the cross section of the white layer was calculated by “Analyze Particle” after a region where two or more particles were connected was cut by “Watershed” in the image after binarization. In the calculation of the average diameter, particles that were spanned on the edge of the image were excluded in order to obtain the correct particle diameter.

SEM images including an area of 26 μm² or more were acquired from the four regions, and the average values of the volume concentration and the average diameter of the fine particles obtained from the SEM images were used as the volume concentration of the fine particles and the average diameter of the fine particles in the cross section of the white layer.
L⁺a⁺b

Measurement was performed using a spectrophotometer (manufactured by Konica Minolta, Inc.) based on JIS-Z8772:2009 geometric condition c.

Far-Infrared Average Transmittance (Wavelength 8 μm to 12 μm) T_{FIR}

Measurement was performed using an infrared spectrophotometer (Nicolet iS10, manufactured by Thermo Fisher Scientific Inc.). Here, the average transmittance is an average value of transmittances of light having a wavelength of 8 μm to 12 μm.

### Refractive Index of Resin Matrix

Measurement was performed using an infrared spectroscopic ellipsometer (MD2000DI manufactured by J. A. Woollam Company). Here, the refractive index is a refractive index for light having a wavelength of 550 nm.

### Arithmetic Average Height Sa

Measurement was performed with a laser microscope (VK-X250, manufactured by KEYENCE Corporation) at a magnification of 150 based on ISO 25178.

Average Length RSm of Roughness Curve Element Measurement was performed with a laser microscope (VK-X250, manufactured by KEYENCE Corporation) at a magnification of 150 based on JIS 0601.

### Root Mean Square Slope RΔq

Measurement was performed with a laser microscope (VK-X250, manufactured by KEYENCE Corporation) at a magnification of 150 based on JIS 0601.

Hereinafter, a method for producing the optical members of Examples 1 to 10 will be described.

### Example 1

A support base material made of Si having a thickness of 0.5 mm was used as a base material. No white layer was formed.

### Example 2

A NiO film was formed as a far-infrared antireflection film on both surfaces of the support base material of Example 1. No white layer was formed. For film formation, a NiO film having a film thickness of about 1.2 μm was formed by a post-oxidation sputtering method using a load-lock sputtering system (RAS-1100BII, manufactured by Syn Corporation Ltd.). Film Formation Conditions for forming the NiO film are as follows.

### NiO Film Formation Conditions

Target: NiO (70 mass %)+Ni (30 mass %) mixed target
Sputtering gas: Ar gas (flow rate: 150 sccm)
Input power: 6 kW
Reactive gas: Ar (flow rate 70 sccm)+O₂ (flow rate: 10 sccm)
RF power: 2 kW
Temperature of support base material: room temperature
Film formation pressure: 0.19 Pa

### Example 3

Both surfaces of a Si substrate having a thickness of 0.5 mm were chemically etched to form irregularities. As the etching solution, KOH, an organic solvent, and a surfactant were used. The composition of the etching solution was adjusted to obtain the arithmetic mean height Sa, the mean length RSm of the roughness curve element, and the root mean square slope RΔq illustrated in Table 1. No white layer was formed.

### Example 4

A member was produced in the same manner as in Example 3, except that the composition of the etching solution was adjusted to obtain the arithmetic mean height Sa, the mean length RSm of the roughness curve element, and the root mean square slope RΔq illustrated in Table 1.

### Example 5

A white layer containing TiO₂ as fine particles and a fluororesin as a resin matrix was formed on the base material of Example 1. The white layer was formed by applying a white layer precursor on the base material by a spin coating method and then drying the precursor at 190° C. for 9 minutes in an electric furnace. The white layer precursor was composed of a fluororesin coating material containing TiO₂ fine particles (BONNFLON GT #2000, manufactured by AGC COAT-TECH Co., Ltd.), a fluororesin coating material (BONNFLON #2050 Clear, manufactured by AGC COAT-TECH Co., Ltd.), and xylene, and the composition was adjusted to obtain the film thickness of the white layer and the fine particle concentration illustrated in Table 1. The TiO₂ fine particles were present as secondary particles in the white layer.

### Examples 6 and 7

An optical member was produced in the same manner as in Example 5 except that the composition of the white layer precursor and the rotation speed of a spin coater were adjusted to obtain the film thickness of the white layer in Table 1.

### Examples 8 to 10

An optical member was produced in the same manner as in Example 5 except that the base material was changed to the base material used in Example 2, and the composition of the white layer precursor and the rotation speed of a spin coater were adjusted to obtain the film thickness of the white layer in Table 1.

The following describes a simulation method of Examples 11 to 19.

### Examples 11 to 19

In order to obtain a correction coefficient and a proportionality coefficient described later, a white layer as a reference (hereinafter, the reference white layer) was actually prepared. A white layer precursor was prepared by dissolving 125 parts by mass of trifunctional alkyl thiol (ACTOCURE SS32, manufactured by Kawaguchi Chemical Industry Co., LTD.) and 2.2 parts by mass of an azo polymerization initiator (V-65, manufactured by Fujifilm Wako Pure Chemical Corporation) in methyl ethyl ketone, with respect to 100 parts by mass of 1,11-dodecadiene (manufactured by Tokyo Chemical Industry Co., Ltd.), adding TiO₂ fine particles thereto, and stirring the mixture under rotation. The white layer precursor was dropped onto the substrate, and then cured by UV irradiation with an exposure machine to form a reference white layer in which the resin matrix was a polyolefin resin.

Details of a verification method of each characteristic will be described below.
L⁺a⁺b⁺

As a refractive index n and an attenuation constant k of the fine particles and the base material, values obtained from a known database such as RefractiveIndex.INFO (https://refractiveindex.info/) were used. As a refractive index n and an attenuation constant k of the resin matrix, measured values were used. Using the optical constants and the particle diameter of the particles as input values, the scattering cross-sectional area σ_{sca} and the absorption cross-sectional area σ_{abs} were calculated based on Mie's scattering theory. Here, the correction coefficient for the scattering cross-sectional area σ_{sca} was calculated so that the spectrum of scattering reflection obtained when the condition of the reference white layer was reproduced coincided with the spectrum of scattering reflection obtained from the reference white layer. Hereinafter, the scattering cross-sectional area σ_{sca} multiplied by the correction coefficient is defined as a scattering cross-sectional area σ_{sca}. The attenuation coefficient K and the scattering coefficient up were calculated from the scattering cross-sectional area ν_{sca}.

The refractive index n and the attenuation constant k of the white layer at each fine particle concentration were calculated by Bruggeman's effective medium approximation. Using the calculated refractive index n and attenuation constant k, Fresnel reflectance r₂₁ at the interface between the white layer and the atmosphere, a Fresnel reflectance r₂₃ at the interface between the white layer and the base material, and a transmittance t₁₂ from the atmosphere to the white layer were calculated. In the calculation of r₂₃, the experimental values obtained from Examples 1 and 2 were used as the value on the base material side.

Equation (1) is an example of an expression representing the scattered electric field intensity. Here, δ represents a phase difference between an incident wave and a reflected wave, and L represents a length (optical path length) of incident light traveling from an atmospheric-white layer interface to a white layer-base material interface.

$$\vert {E}_{s} \vert = {E}_{0} {t}_{12} \sqrt{( 1 - {e}^{2 μ L} \frac{{e}^{- 2 KL} cos δ ( 1 - {r}_{23}^{2} {r}_{21}^{2} {e}^{- 4 KL} )}{1 - 2 {r}_{23}^{2} {r}_{21}^{2} {e}^{- 4 KL} cos 2 δ + {r}_{23}^{4} {r}_{21}^{4} {e}^{- BKL}} )} \qquad ( 1 )$$

For Equation (1), the spectrum of the D65 light source was applied as the incident light source, and the scattering intensity was integrated over the entire region with respect to the incident angle to calculate the spectrum of the scattering reflection. The spectrum of scattered reflection was converted into CIE XYZ space by mathematical conversion conforming to CIE 1976, and the CIE XYZ space was further converted to calculate L⁺a⁺b⁺.

### Far-Infrared Average Transmittance

Similarly to the calculation of L⁺a⁺b⁺, the refractive index n, the scattering cross-sectional area Caca, and the absorption cross-sectional area σ_{sbs} were calculated in consideration of effective medium approximation and Mie scattering. Next, the attenuation constant k was calculated so that the transmittance calculated when the conditions of the reference white layer were reproduced coincided with the transmittance of the reference white layer. In this case, the refractive index was calculated as a film having visible monodispersion. The attenuation coefficient κ is proportional to the scattering cross-sectional area σ_{sca} and the absorption cross-sectional area σ_{sbs}, and a proportional constant is obtained by dividing the scattering cross-sectional area σ_{sca} and the absorption cross-sectional area σ_{sbs} by the attenuation coefficient κ. From the proportionality coefficient, and the scattering cross-sectional area σ_{sca} and the absorption cross-sectional area σ_{sbs}, at each particle diameter, pseudo n and k of the white layer for each particle diameter were obtained. Using optical thin film simulation software (TFCalc, manufactured by Software Spectra Inc.), the average transmittance of far-infrared rays under the following conditions was calculated from pseudo n and k.
Viewing angle: 2 degrees
Polarization: p and s mixed
Incident angle: 0 degrees

The values of the characteristics of Examples 1 to 19 are illustrated in Tables 1 and 2. In a case of having a far-infrared antireflection film, the column of “Far-infrared antireflection film” was described as “0”. The results of measuring L⁺a⁺b⁺, T_{FIR}, Sa, RSm, and RΔq on the light incident surface of each sample are illustrated in Tables 1 and 2.

TABLE 1

| | | Exam- | Exam- | Exam- | Exam- | Exam- | Exam- | Exam- | Exam- | Exam- | Exam- |
|---|---|---|---|---|---|---|---|---|---|---|---|
| | | ple 1 | ple 2 | ple 3 | ple 4 | ple 5 | ple 6 | ple 7 | ple 8 | ple 9 | ple 10 |
| Material of fine particles | | — | — | — | — | TiO₂ | TiO₂ | TiO₂ | TiO₂ | TiO₂ | TiO₂ |
| Average diameter of fine | | — | — | — | — | 0.24 | 0.24 | 0.24 | 0.24 | 0.24 | 0.24 |
| particles [μm] | | | | | | | | | | | |
| Fine particle | | — | — | — | — | 22.7 | 22.7 | 22.7 | 22.7 | 22.7 | 22.7 |
| concentration [vol %] | | | | | | | | | | | |
| Resin matrix | | — | — | — | — | Fluororesin | Fluororesin | Fluororesin | Fluororesin | Fluororesin | Fluororesin |
| Refractive index of resin | | — | — | — | — | 1.27 | 1.27 | 1.27 | 1.27 | 1.27 | 1.27 |
| matrix | | | | | | | | | | | |
| Thickness of white layer | | — | — | — | — | 5.87 | 2.02 | 1.45 | 5.31 | 4.04 | 1.21 |
| [μm] | | | | | | | | | | | |
| Sa [μm] | | 0.0 | — | 0.2 | 1.0 | — | — | — | — | — | — |
| RSm [μm] | | 36.6 | — | 6.6 | 15.0 | — | — | — | — | — | — |
| RΔq [°] | | 1.0 | — | 46.1 | 43.3 | — | — | — | — | — | — |
| Far-infrared | Light | — | ◯ | — | — | — | — | — | ◯ | ◯ | ◯ |
| antireflection | incident | | | | | | | | | | |
| film | side | | | | | | | | | | |
| | Light | — | ◯ | — | — | — | — | — | ◯ | ◯ | ◯ |
| | emitting | | | | | | | | | | |
| | side | | | | | | | | | | |

| | | | | | | | | | | |
|---|---|---|---|---|---|---|---|---|---|---|
| L* | 1.0 | 0.6 | 44.5 | 40.6 | 85.8 | 70.6 | 65.1 | 86.2 | 83.2 | 58.5 |
| a* | 0.1 | 0.1 | 0.4 | 0.3 | −1.9 | −2.6 | −2.6 | −1.9 | −2.1 | −3.0 |
| b* | −0.2 | −0.1 | −6.9 | −7.1 | −3.7 | −9.3 | −8.9 | −3.6 | −4.9 | −9.6 |
| T_{FIR} [%] | 49.5 | 79.0 | 51.9 | 0.3 | 25.3 | 38.0 | 42.4 | 35.6 | 41.3 | 65.5 |
| L* + T_{FIR} | 50.5 | 79.6 | 96.4 | 40.9 | 111.1 | 108.6 | 107.5 | 121.8 | 124.5 | 124.0 |

TABLE 2

| | | Example | Example | Example | Example | Example | Example | Example | Example | Example |
|---|---|---|---|---|---|---|---|---|---|---|
| | | 11 | 12 | 13 | 14 | 15 | 16 | 17 | 18 | 19 |
| Material of fine particles | | TiO₂ | TiO₂ | TiO₂ | TiO₂ | TiO₂ | SiO₂ | MgO | TiO₂ | TiO₂ |
| Average diameter of fine | | 0.8 | 0.4 | 0.2 | 2 | 0.05 | 0.4 | 0.4 | 0.4 | 0.4 |
| particles [μm] | | | | | | | | | | |
| Fine particle | | 20 | 20 | 20 | 20 | 20 | 20 | 20 | 20 | 17 |
| concentration [vol %] | | | | | | | | | | |
| Resin matrix | | Polyolefin | Polyolefin | Polyolefin | Polyolefin | Polyolefin | Polyolefin | Polyolefin | Polyolefin | Polyolefin |
| | | resin | resin | resin | resin | resin | resin | resin | resin | resin |
| Refractive index of resin | | 1.3 | 1.3 | 1.3 | 1.3 | 1.3 | 1.3 | 1.3 | 1.3 | 1.3 |
| matrix | | | | | | | | | | |
| Thickness of white layer | | 6 | 6 | 6 | 6 | 6 | 6 | 6 | 5 | 50 |
| [μm] | | | | | | | | | | |
| Sa [μm] | | — | — | — | — | — | — | — | — | — |
| RSm [μm] | | — | — | — | — | — | — | — | — | — |
| RΔq[°] | | — | — | — | — | — | — | — | — | — |
| Far-infrared | Light | — | — | — | — | — | — | — | ◯ | ◯ |
| antireflection | incident | | | | | | | | | |
| film | side | | | | | | | | | |
| | Light | — | — | — | — | — | — | — | ◯ | ◯ |
| | emitting | | | | | | | | | |
| | side | | | | | | | | | |

| | | | | | | | | | |
|---|---|---|---|---|---|---|---|---|---|
| L* | 73.9 | 84.4 | 86.0 | 57.7 | 26.4 | 41.9 | 41.9 | 81.9 | 92.6 |
| a* | −8.2 | −5.4 | −12.9 | −8.7 | −2.0 | −4.4 | −4.4 | −4.9 | −7.0 |
| b* | 3.2 | 2.5 | 1.1 | 8.3 | −26.3 | −14.1 | −14.1 | 3.3 | −3.8 |
| T_{FIR} [%] | 30.4 | 69.1 | 76.6 | 0.0 | 77.4 | 62.2 | 78.4 | 78.0 | 44.0 |
| L* + T_{FIR} | 104.3 | 153.5 | 162.6 | 57.7 | 103.8 | 104.1 | 120.3 | 159.9 | 136.6 |

As illustrated in Tables 1 and 2, in the member having the white layer, it has been found that both the enhanced far-infrared transmittance properties and the white appearance can be achieved by appropriately controlling the material, concentration, and particle diameter of the fine particles, the material of the resin matrix, the thickness of the white layer, in conjunction with providing the far-infrared antireflection film. That is, in Examples 5 to 13, 18, and 19 as examples, since L⁺ is 50 or more, a⁺ is −15 or more and 15 or less, b is −15 or more and 15 or less, and T_{FIR} is 20% or more, both the enhanced far-infrared transmittance properties and the white appearance can be achieved. On the other hand, in Examples 1 to 4 and 14 to 17 as comparative examples, it has been found that at least one of these requirements is not satisfied, and both the enhanced far-infrared transmittance properties and the white appearance cannot be achieved.

Examples 3 and 4 are comparative examples relating to an optical member having a plurality of fine irregularities on the surface. Although a higher L⁺ than that of Example 1 was exhibited in Example 3 due to an appropriate irregularity structure thereof, which scatters visible light and transmits far-infrared rays, a value sufficient for obtaining a white appearance was not exhibited. Example 4 is an example having a coarser irregularity structure than Example 3. In Example 4, L⁺ was about the same as that in Example 3, but far-infrared rays were hardly transmitted.

Examples 5 to 7 are examples in which the resin matrix is a fluororesin, the fine particles are TiO₂, and the far-infrared antireflection film is not provided. In Examples 5 to 7, the fine particle concentration and the particle diameter of fine particles are constant, and only the film thickness of the white layer is different.

Examples 8 to 10 are examples in which the resin matrix is a fluororesin, the fine particles are TiO₂, and the far-infrared antireflection film is provided. In Examples 8 to 10, the fine particle concentration and the particle diameter of fine particles are constant, and only the film thickness of the white layer is different.

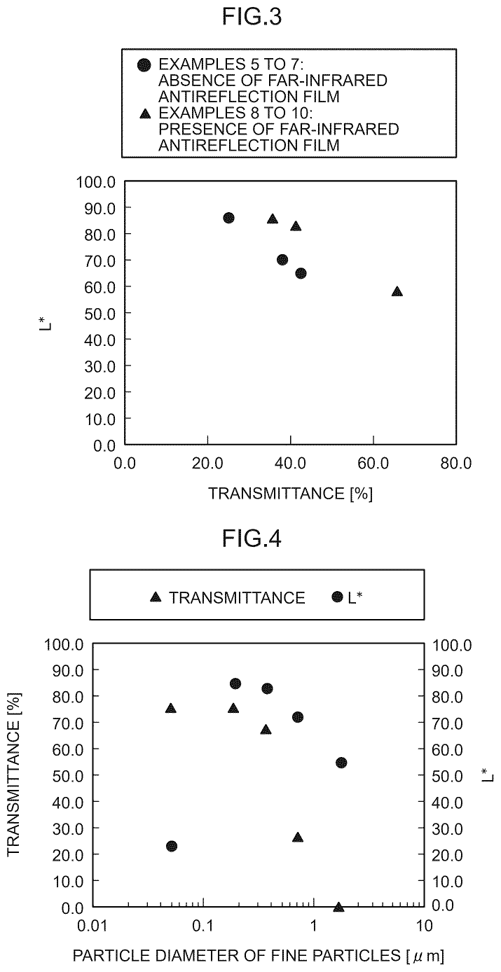

FIG. 3 illustrates the relationship between the far-infrared transmittance and L⁺ in Examples 5 to 7 and 8 to 10. In each of Examples 5 to 7 and 8 to 10, the far-infrared transmittance decreased as L⁺ increased. This is considered to be because as the film thickness of the white layer increases, the amount of fine particles in the white laver increases, leading to an increase in scattering of visible light, while the amount of the resin matrix that absorbs far-infrared rays also increases, resulting in much absorption of far-infrared rays. In addition, it has been found from FIG. 3 that, by providing the far-infrared antireflection film, a higher far-infrared transmittance can be achieved while exhibiting L⁺ comparable to that of a member that does not include a far-infrared antireflection film.

Examples 1 to 15 are examples in which the resin matrix is a polyolefin resin, the fine particles are TiO₂, and the far-infrared antireflection film is not provided. Example 13 has the fine particle concentration, the particle diameter of fine particles, and the film thickness of the white layer comparable to those of Example 5, except that the resin matrix is a polyolefin resin rather than a fluororesin. Example 13 exhibited L similar to that of Example 5, but the far-infrared transmittance of Example 13 had a value significantly higher than that of Example 5. It is considered that the enhanced far-infrared transmittance properties can be obtained by using a resin that absorbs less far-infrared rays as the resin matrix.

FIG. 4 illustrates the relationship between the particle diameter of the fine particle, the far-infrared transmittance, and L⁺ of Examples 11 to 15. FIG. 4 illustrates that the far-infrared transmittance tends to decrease as the particle diameter of fine particles increases. It is considered that when the particle diameter of the fine particles is excessive, scattering of far-infrared rays by the fine particles increases, resulting in a decrease in the far-infrared transmittance.

From FIG. 4, L⁺ tended to increase with an increase in the particle diameter of fine particles and then decrease. It is considered that, by setting the particle diameter of fine particles within an appropriate range, visible light is sufficiently scattered, thereby obtaining a high L⁺.

Examples 16 and 17 are examples in which the material of the fine particles is changed from Example 12. Examples 16 and 17 exhibited significantly lower L⁺ than that of Example 12. It is considered that SiO₂ and MgO have a lower scattering coefficient for visible light than TiO₂, and a high L⁺ is less likely to be obtained when used as fine particles. However, even in a case where SiO₂ or MgO is used as fine particles, for example, a higher L⁺ can be obtained by appropriately increasing the thickness of the white layer and the fine particle concentration as compared with the configurations of Examples 16 and 17. However, in a case where the thickness of the white layer or the fine particle concentration is increased, the far-infrared transmittance decreases.

Among Examples 12, 16, and 17, Example 17 exhibited the highest value for the far-infrared transmittance. The high far-infrared transmittance of Example 17 is considered to be due to the enhanced far-infrared transmittance properties of MgO.

Examples 18 and 19 are examples in which the resin matrix is a polyolefin resin, the fine particles are TiO₂, and the far-infrared antireflection film is provided. Example 18 had the fine particle concentration and the particle diameter of fine particles comparable to those of Example 12 and exhibited L⁺ comparable thereto, but the far-infrared transmittance exhibited a higher value than Example 12. It has been found that even in the example in which the resin matrix is a polyolefin resin, a higher far-infrared transmittance can be obtained by providing the far-infrared antireflection film.

Example 19 is an example in which the film thickness of the white layer is particularly large. From Example 19, it has been found that, by using a resin having low far-infrared ray absorption for the resin matrix, a relatively high far-infrared transmittance can be obtained even when the thickness of the white layer is large.

Example 15 exhibited less than −25 of b⁺. In Example 15, it is considered that b⁺ having a large absolute value was exhibited by the Mie resonance. Present disclosure may provide optical members and the like having structures described in 1 to 12 below.
1. An optical member, wherein in a CIE 1976 (L⁺, a b⁺) color space measured by an SCE method based on geometric condition c of JIS-Z8772:2009, L⁺ is 50 or more, a⁺ is −15 or more and 15 or less, and b⁺ is −15 or more and 15 or less, and an average transmittance T_{FIR} (%) of light having a wavelength of 8 μm to 12 μm satisfies T_{FIR}≥20.
2. The optical member according to 1, wherein (L⁺+T_{FIR})≥115.
3. The optical member according to 1 or 2 comprising: a resin matrix; a white layer containing fine particles dispersed in the resin matrix; and a base material containing a support base material.
4. The optical member according to 3, wherein the white layer has a thickness of 1 μm or more and less than 10 μm.
5. The optical member according to 3 or 4, wherein an average diameter of the fine particles in a cross section of the white layer is 0.1 μm to 1 μm.
6. The optical member according to any one of 3 to 5, wherein a volume concentration of the fine particles in the white laver is 4% to 80%.
7. The optical member according to any one of 3 to 6, wherein the fine particles contain at least one selected from the group consisting of TiO₂, ZrO₂, Nb₂O, and Ta₂O₅.
8. The optical member according to one of 3 to 6, wherein the support base material includes at least one selected from the group consisting of a Si base material, a Ge base material, a ZnS base material, and a chalcogenide glass base material.
9. The optical member according to any one of 3 to 8, wherein the resin matrix contains at least one of a fluororesin or a polyolefin resin.
10. The optical member according to any one of 3 to 9, wherein the base material includes a far-infrared antireflection film that minimizes reflection of light having a wavelength of 8 μm to 12 μm.
11. The optical member according to 10, wherein the far-infrared antireflection film contains at least one selected from the group consisting of NiO, diamond-like carbon, ZrO₂, ZnS, ZnSe, Ge, Si, MgO, ZnO, YF₃, and MgF₂.
12. A far-infrared sensor module using the optical member according to any one of 1 to 11.

According to the present invention, it is possible to provide the optical member that appropriately transmits far-infrared rays having a wavelength of 8 μm to 12 μm and exhibits white color.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical member, wherein
in a CIE 1976 (L⁺, a⁺, b⁺) color space measured by an SCE method based on geometric condition c of JIS-Z8772:2009, L⁺ is 50 or more, a⁺ is −15 or more and 15 or less, and b⁺ is −15 or more and 15 or less, and
an average transmittance T_{FIR} (%) of light having a wavelength of 8 μm to 12 μm satisfies T_{FIR}≥20.

2. The optical member according to claim 1, wherein (L⁺+T_{FIR})≥115.

3. The optical member according to claim 1, comprising:
a resin matrix;
a white layer containing fine particles dispersed in the resin matrix; and
a base material containing a support base material.

4. The optical member according to claim 3, wherein the white layer has a thickness of 1 μm or more and less than 10 μm.

5. The optical member according to claim 3, wherein an average diameter of the fine particles in a cross section of the white layer is 0.1 μm to 1 μm.

6. The optical member according to claim 3, wherein a volume concentration of the fine particles in the white layer is 4% to 80%.

7. The optical member according to claim 3, wherein the fine particles contain at least one selected from the group consisting of TiO₂, ZrO₂, Nb₂O₅, and Ta₂O₅.

8. The optical member according to claim 3, wherein the support base material includes at least one selected from the group consisting of a Si base material, a Ge base material, a ZnS base material, and a chalcogenide glass base material.

9. The optical member according to claim 3, wherein the resin matrix contains at least one of a fluororesin or a polyolefin resin.

10. The optical member according to claim 3, wherein the base material includes a far-infrared antireflection film that minimizes reflection of light having a wavelength of 8 μm to 12 μm.

11. The optical member according to claim 10, wherein the far-infrared antireflection film contains at least one selected from the group consisting of NiO, diamond-like carbon, ZrO₂, ZnS, ZnSe, Ge, Si, MgO, ZnO, YF₃, and MgF₂.

12. A far-infrared sensor module using the optical member according to claim 1.
